(19) United States
(12) Patent Application Publication
(10) Pub. No.: US 2025/0239497 A1
(43) Pub. Date: Jul. 24, 2025

(54) CAVITY TAPE FOR PACKAGE PROTECTION

(71) Applicant: Western Digital Technologies, Inc., San Jose, CA (US)

(72) Inventors: Ankit Kumar, Nalanda (IN); Xu Chen, Shanghai (CN); Rui Guo, Shanghai (CN); Shaopeng Dong, Shanghai (CN); Jihao Tang, Shanghai (CN); Wenbin Qu, Shanghai (CN); Fen Yu, Shanghai (CN); Pradeep Kumar Rai, Milpitas, CA (US)

(73) Assignee: Western Digital Technologies, Inc., San Jose, CA (US)

(21) Appl. No.: 18/419,588

(22) Filed: Jan. 23, 2024

(51) Int. Cl. H01L 23/10; H01L 23/00; H01L 23/31; H01L 23/495; H01L 23/552

(52) U.S. Cl. CPC H01L 23/10; H01L 23/315; H01L 23/49572; H01L 23/552; H01L 24/94; H01L 24/16; H01L 24/32; H01L 24/48; H01L 24/73; H01L 2224/16227; H01L 2224/32225; H01L 2224/48228; H01L 2224/73204; H01L 2224/94; H01L 2924/1438

(57) ABSTRACT

An apparatus includes a tape having a tape thickness extending from a first surface to a second surface and a plurality of cavities formed in the first surface. Each cavity has dimensions along the first surface that are less than dimensions of a corresponding package. Each cavity has a cavity depth that is less than the tape thickness such that a base portion of the tape has a base thickness that is less than the tape thickness.

### BACKGROUND

The present technology relates to packages that include one or more semiconductor dies (e.g., in memory systems) and to protecting such packages to avoid damage.

Semiconductor memory devices have become more popular for use in various electronic devices. For example, non-volatile semiconductor memory is used in cellular telephones, digital cameras, personal digital assistants, mobile computing devices, non-mobile computing devices and other devices (host devices).

A memory device includes memory cells, which may be arranged in series, in NAND strings, for example. One or more memory package or memory die may be connected to a memory controller formed on another die (e.g., a separate IC on another substrate). Dies such as memory and controller dies may be encapsulated, packaged, or otherwise configured protected from environmental damage. A package for one or more such dies may include pads on which solder balls are located for connection of dies to external circuits (e.g., on a PCB). Such solder balls may be prone to damage during certain process steps. Adequately protecting packages and solder balls located on packages during subsequent processing may be challenging.

### BRIEF DESCRIPTION OF THE DRAWINGS

Like-numbered elements refer to common components in the different Figures.

FIG. 1 is a block diagram of one embodiment of a memory system connected to a host.

FIG. 2A is a functional block diagram of an embodiment of a memory die.

FIG. 2B is a functional block diagram of an embodiment of an integrated memory assembly.

FIGS. 3A-C illustrate examples of packages.

FIGS. 4A-B show an example of solder balls on a package.

FIGS. 5A-C illustrate an example of window tape to protect packages.

FIG. 6 illustrates an example of a solder embedded tape.

FIGS. 7A-C show an example of a cavity tape protecting a package with solder balls not contacting the cavity tape.

FIGS. 8A-B show an example of a cavity tape with solder balls contacting cavity tape with solder balls contacting the cavity tape.

FIGS. 9A-C show an example of forming a cavity tape from a window tape and base tape.

FIGS. 10A-C show an example of forming a cavity tape using a masking layer.

FIGS. 11A-C illustrate a cavity tape protecting packages with solder balls.

FIG. 12 illustrates an example of a method that uses cavity tape.

FIGS. 13A-B illustrate examples of methods of using cavity tape.

### DETAILED DESCRIPTION

Techniques and apparatuses are disclosed herein to protect packages, including packages that have solder balls extending from a surface (e.g., during certain process steps that might cause damage). For example, packages (e.g., integrated circuit packages that include one or more integrated circuit dies) may have solder balls extending from a surface for bonding to form electrical connections with the packages (e.g., bonding packages to a printed circuit board or PCB). Solder balls may be subject to damage during certain process steps. For example, a layer may be added to surfaces of packages to protect them from Electromagnetic Interference (EMI). Such a layer may be formed of an electrically conductive material such as one or more metal. Aspects of the present technology are directed to protecting packages, including packages with solder balls, during potentially-damaging process steps (e.g., during deposition of a metal layer for EMI protection).

The present technology includes using a cavity tape that has cavities corresponding to packages to be protected. For example, each cavity may have dimensions along the upper surface of the cavity tape that are less than dimensions of a corresponding package (e.g., providing some overlap to enable adhesion and to seal the cavities). Each cavity may have a cavity depth that is less than the tape thickness such that a base portion of the tape extends under the cavity (e.g., there is some base thickness under cavities).

Aspects of the present technology provide solutions to technical problems of protecting solder balls on a surface of a package during process steps such as deposition of an electrically conductive layer on the package. Technical solutions are described that use cavity tape to protect solder balls from potential damage during deposition of electrically conductive material that might otherwise cause unwanted electrical connections (e.g., short circuits).

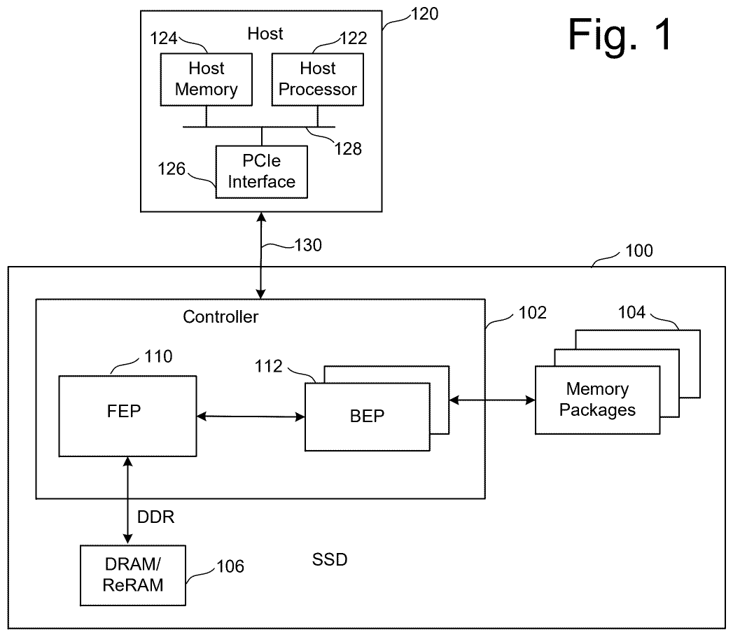

FIG. 1 is a block diagram of one embodiment of a memory system 100 (data storage system) connected to a host 120. Memory system 100 can be configured to implement aspects of the technology proposed herein. Many different types of memory systems can be used with the technology proposed herein. One example memory system is a solid-state drive (“SSD”); another is a System in Package (SIP) memory in consumer electronic products; however, other types of memory systems can also be used. Memory system 100 comprises a Controller 102, nonvolatile memory 104 for storing data, and local memory (e.g., DRAM/ReRAM) 106. Controller 102 comprises a Front-End Processor Circuit (FEP) 110 and one or more Back End Processor Circuits (BEP) 112. In one embodiment FEP circuit 110 is implemented on an ASIC. In one embodiment, each BEP circuit 112 is implemented on a separate ASIC. The ASICs for each of the BEP circuits 112 and the FEP circuit 110 are implemented on the same semiconductor such that the Controller 102 is manufactured as a System on a Chip (“SoC”). FEP 110 and BEP 112 both include their own processors. In one embodiment, FEP circuit 110 and BEP 112 work as a master slave configuration where the FEP circuit 110 is the master, and each BEP 112 is a slave. For example, FEP circuit 110 implements a flash translation layer that performs memory management (e.g., garbage collection, wear leveling, etc.), logical to physical address translation, communication with the host, management of DRAM (local volatile memory) and management of the overall operation of the SSD (or other nonvolatile data storage system). The BEP circuit 112 manages memory operations in the memory packages/die at the request of FEP circuit 110. For example, the BEP circuit 112 can carry out the read, erase and programming processes. Additionally, the BEP circuit 112 can perform buffer management, set specific voltage levels required by the FEP circuit 110, perform error correction (ECC), control the Toggle Mode interfaces to the memory packages, etc. In one embodiment, each BEP circuit 112 is responsible for its own set of memory packages. Controller 102 is one example of a control circuit.

In one embodiment, nonvolatile memory 104 comprises a plurality of memory packages. Each memory package includes one or more memory die. Therefore, Controller 102 is connected to one or more nonvolatile memory die. In one embodiment, each memory die in the memory packages 14 utilizes NAND flash memory (including two-dimensional NAND flash memory and/or three-dimensional NAND flash memory). In other embodiments, the memory package can include other types of memory.

Controller 102 communicates with host 120 via an interface 130. For example, interface 130 may be configured according to a standard such as a SIP memory standard, the Secure Digital (SD) standard and/or the Non Volatile Memory express (NVMe) standard (e.g., using PCI Express (PCIe)). For working with memory system 100, host 120 includes a host processor 122, host memory 124, and in this example a PCIe interface 126 connected to bus 128. Host memory 124 is the host's physical memory, and can be DRAM, SRAM, nonvolatile memory or another type of storage. Host 120 is external to and separate from memory system 100. In one embodiment, memory system 100 is embedded in host 120.

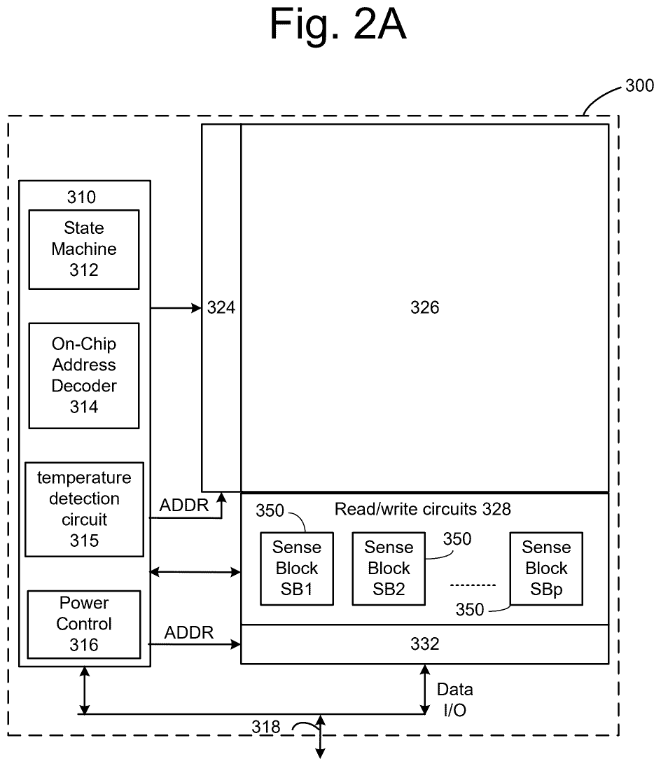

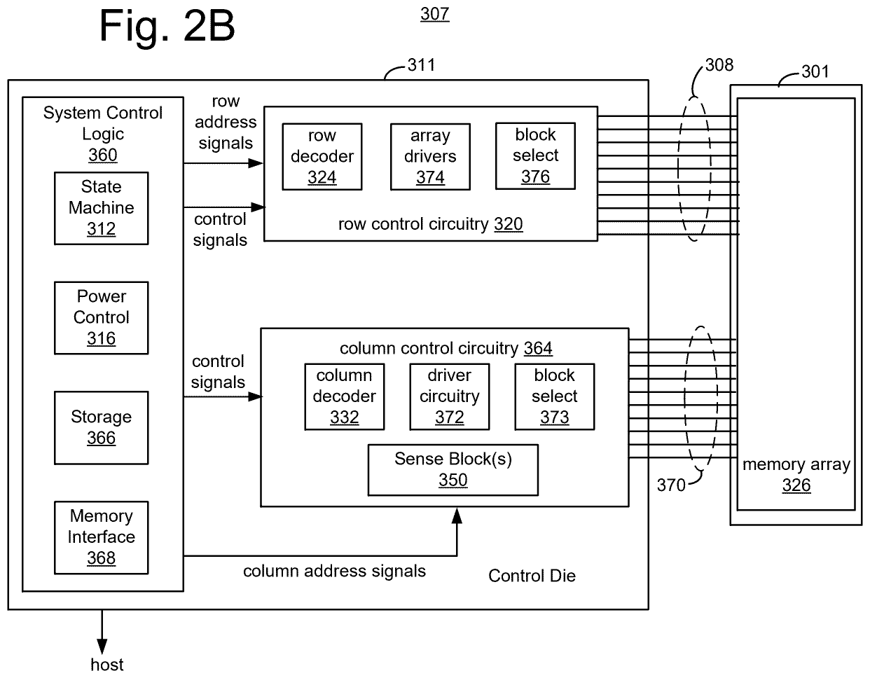

FIG. 2A is a functional block diagram of one embodiment of a memory die 300. Each of the one or more memory die 300 of FIG. 1D can be implemented as memory die 300 of FIG. 2A. The components depicted in FIG. 2A are electrical circuits. In one embodiment, each memory die 300 includes a memory structure 326, control circuits 310, and read/write circuits 328, all of which are electrical circuits. Memory structure 326 is addressable by word lines via a row decoder 324 and by bit lines via a column decoder 332. The read/write circuits 328 include multiple sense blocks 350 including SB1, SB2, . . . , SBp (sensing circuits) and allow a page (or multiple pages) of data in multiple memory cells to be read or programmed in parallel. In one embodiment, each sense block includes a sense amplifier and a set of latches connected to the bit line. The latches store data to be written and/or data that has been read. The sense blocks include bit line drivers.

Commands and data are transferred between the controller and the memory die 300 via lines 318, which may form a bus between memory die 300 and the controller (e.g., memory bus 294). In one embodiment, memory die 300 includes a set of input and/or output (I/O) pins that connect to lines 318.

Control circuits 310 cooperate with the read/write circuits 328 to perform memory operations (e.g., write, read, erase, and others) on memory structure 326. In one embodiment, control circuits 310 includes a state machine 312, an on-chip address decoder 314, a power control module 316 (power control circuit) and a temperature detection circuit 315. State machine 312 provides die-level control of memory operations. In one embodiment, state machine 312 is programmable by software. In other embodiments, state machine 312 does not use software and is completely implemented in hardware (e.g., electrical circuits). In some embodiments, state machine 312 can be replaced by a microcontroller or microprocessor. In one embodiment, control circuits 310 include buffers such as registers, ROM fuses and other storage packages for storing default values such as base voltages and other parameters.

The on-chip address decoder 314 provides an address interface between addresses used by controller 102 to the hardware address used by the decoders 324 and 332. Power control module 316 controls the power and voltages supplied to the word lines and bit lines during memory operations. Power control module 316 may include charge pumps for creating voltages.

For purposes of this document, control circuits 310, alone or in combination with read/write circuits 328 and decoders 324/332, comprise one or more control circuits for memory structure 326. These one or more control circuits are electrical circuits that perform the functions described below in the flow charts and signal diagrams. In other embodiments, the one or more control circuits can consist only of controller 102, which is an electrical circuit in combination with software, which performs the functions described below in the flow charts and signal diagrams. In another alternative, the one or more control circuits comprise controller 102 and control circuits 310 performing the functions described below in the flow charts and signal diagrams. In another embodiment, the one or more control circuits comprise state machine 312 (or a microcontroller or microprocessor) alone or in combination with controller 102.

In one embodiment, memory structure 326 comprises a monolithic three-dimensional memory array of nonvolatile memory cells in which multiple memory levels are formed above a single substrate, such as a wafer. The memory structure may comprise any type of nonvolatile memory that is monolithically formed in one or more physical levels of arrays of memory cells having an active area disposed above a silicon (or other type of) substrate. In one example, the nonvolatile memory cells of memory structure 326 comprise vertical NAND strings with charge-trapping material such as described, for example, in U.S. Pat. No. 9,721,662, incorporated herein by reference in its entirety. In another embodiment, memory structure 326 comprises a two-dimensional memory array of nonvolatile memory cells. In one example, the nonvolatile memory cells are NAND flash memory cells utilizing floating gates such as described, for example, in U.S. Pat. No. 9,082,502, incorporated herein by reference in its entirety. Other types of memory cells (e.g., NOR-type flash memory) can also be used.

In one embodiment, the control circuit(s) (e.g., control circuits 310) are formed on a first die, referred to as a control die, and the memory array (e.g., memory structure 326) is formed on a second die, referred to as a memory die. For example, some or all control circuits (e.g., control circuit 310, row decoder 324, column decoder 332, and read/write circuits 328) associated with a memory may be formed on the same control die. A control die may be bonded to one or more corresponding memory die to form an integrated memory assembly. The control die and the memory die may have bond pads arranged for electrical connection to each other. Bond pads of the control die and the memory die may be aligned and bonded together by any of a variety of bonding techniques, depending in part on bond pad size and bond pad spacing (i.e., bond pad pitch). In some embodiments, the bond pads are bonded directly to each other, without solder or other added material, in a so-called Cu-to-Cu bonding process. In some examples, dies are bonded in a one-to-one arrangement (e.g., one control die to one memory die). In some examples, there may be more than one control die and/or more than one memory die in an integrated memory assembly. In some embodiments, an integrated memory assembly includes a stack of multiple control die and/or multiple memory die. In some embodiments, the control die is connected to, or otherwise in communication with, a memory controller. For example, a memory controller may receive data to be programmed into a memory array. The memory controller will forward that data to the control die so that the control die can program that data into the memory array on the memory die.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 307. One or more integrated memory assemblies 307 may be used in a memory package 104 in memory system 100. The integrated memory assembly 307 includes two types of semiconductor die (or more succinctly, “die”). Memory die 301 includes memory array 326 (memory structure). Memory array 326 may contain nonvolatile memory cells.

Control die 311 includes column control circuitry 364, row control circuitry 320 and system control logic 360 (including state machine 312, power control module 316, storage 366, and memory interface 368). In some embodiments, control die 311 is configured to connect to the memory array 326 in the memory die 301. FIG. 2B shows an example of the peripheral circuitry, including control circuits, formed in a peripheral circuit or control die 311 coupled to memory array 326 formed in memory die 301. System control logic 360, row control circuitry 320, and column control circuitry 364 are located in control die 311. In some embodiments, all or a portion of the column control circuitry 364 and all or a portion of the row control circuitry 320 are located on the memory die 301. In some embodiments, some of the circuitry in the system control logic 360 is located on the on the memory die 301.

System control logic 360, row control circuitry 320, and column control circuitry 364 may be formed by a common process (e.g., CMOS process), so that adding elements and functionalities, such as ECC, more typically found on a memory controller 102 may require few or no additional process steps (i.e., the same process steps used to fabricate controller 102 may also be used to fabricate system control logic 360, row control circuitry 320, and column control circuitry 364). Thus, while moving such circuits from a die such as memory die 301 may reduce the number of steps needed to fabricate such a die, adding such circuits to a die such as control die 311 may not require many additional process steps.

FIG. 2B shows column control circuitry 364 including sense block(s) 350 on the control die 311 coupled to memory array 326 on the memory die 301 through electrical paths 370. For example, electrical paths 370 may provide electrical connection between column decoder 332, driver circuitry 372, and block select 373 and bit lines of memory array (or memory structure) 326. Electrical paths may extend from column control circuitry 364 in control die 311 through pads on control die 311 that are bonded to corresponding pads of the memory die 301, which are connected to bit lines of memory structure 326. Each bit line of memory structure 326 may have a corresponding electrical path in electrical paths 370, including a pair of bond pads, which connects to column control circuitry 364. Similarly, row control circuitry 320, including row decoder 324, array drivers 374, and block select 376 are coupled to memory array 326 through electrical paths 308. Each of electrical paths 308 may correspond to a word line, dummy word line, or select gate line. Additional electrical paths may also be provided between control die 311 and memory structure die 301.

In some embodiments, there is more than one control die 311 and/or more than one memory die 301 in an integrated memory assembly 307. In some embodiments, the integrated memory assembly 307 includes a stack of multiple control die 311 and multiple memory structure die 301. In some embodiments, each control die 311 is affixed (e.g., bonded) to at least one of the memory structure dies 301.

The exact type of memory array architecture or memory cell included in memory structure 326 is not limited to the examples above. Many different types of memory array architectures or memory cell technologies can be used to form memory structure 326. No particular nonvolatile memory technology is required for purposes of the new claimed embodiments proposed herein. Other examples of suitable technologies for memory cells of the memory structure 326 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 326 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory package is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

Semiconductor dies may be packaged prior to being integrated into larger assemblies. For example, one or more semiconductor die may be mounted on a substrate and encapsulated in an electrically insulating material in order to protect the die and circuits in the die. Such packaged dies, or “packages” may contain one or more dies (e.g., a memory package may include one or more memory die and/or integrated memory assembly).

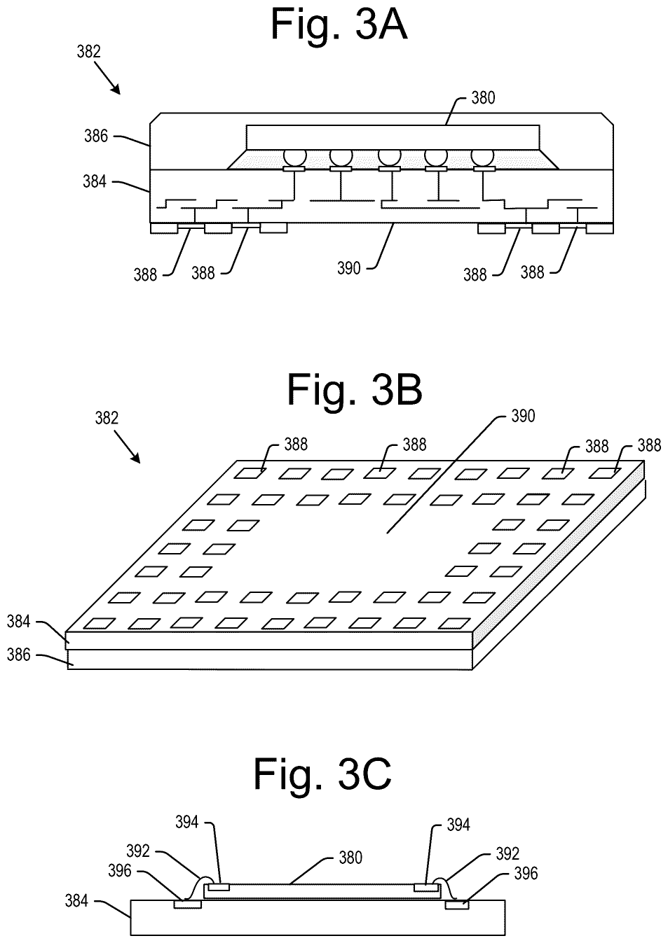

FIG. 3A shows a first example of a die 380 (e.g., memory die 300, integrated memory assembly 307, memory controller 102 or other die) that is packaged (encapsulated) to form an integrated circuit package or package 382. Semiconductor die 380 may be mounted to the first major planar surface of a substrate 384. It will be understood that the semiconductor die 380 may be any type of semiconductor dies, including a semiconductor memory die. The semiconductor die 380 may be flip-chip mounted to contact pads on the top surface of substrate 384 using solder balls to physically and electrically couple the semiconductor die 380 to substrate 384.

To the extent a space exists between die 380 and the top major planar surface of substrate 384, that space may be under filled with a suitable material. The underfill material may be thermally conductive and electrically insulating, such as for example various thermally conductive polymers, or dielectric solder alloy. The underfill material may be omitted in further embodiments.

A panel of semiconductor packages like package 382 may be encapsulated in a mold compound 386 as shown in FIG. 3A. Mold compound 386 may include for example solid epoxy resin, Phenol resin, fused silica, crystalline silica, carbon black and/or metal hydroxide. Other mold compounds are contemplated. The mold compound 386 may be applied by various known processes, including by FFT (flow free thin) molding, compression molding, transfer molding or injection molding techniques.

FIG. 3A shows pads 388 located on bottom major planar surface 390 of substrate 384. Pads 388 are connected through substrate 384 with corresponding pads on the opposite surface of substrate 384, which are connected with corresponding pads of semiconductor die 380. Pads 388 provide electrical connections that may facilitate various functions (e.g., providing voltages such as supply voltages to semiconductor die 380 and providing connections for sending data to and/or from semiconductor die 380). Pads 388 may enable electrical connection of package 382 in a larger assembly (e.g., connection to a Printed Circuit Board (PCB), which may have multiple semiconductor dies).

FIG. 3B shows bottom surface 390 of substrate 384 in perspective view including pads 388.

While FIGS. 3A-B show an example of package 382 in which a single die, die 380, is attached to substrate 384 in a flip-chip arrangement, the present technology is not limited to any particular number of die or any particular packaging technique. Aspects of the present technology may be applied to any number of dies packaged in any suitable manner. For example, FIG. 3C shows die 380 attached to substrate 384 using wire bonding, including wire bonds 392 connecting die pads 394 and substrate pads 396 as an alternative to flip-chip (additional features are omitted for simplicity). While a single die 380 is shown for simplicity of illustration, examples may include multiple dies, which may be the same or different. For example, a SIP memory package may include multiple memory (e.g., NAND) chips (e.g., 2 dies, 4 dies, 8 dies, 16 or more dies) and may also include one or more ASIC.

In order to connect package 382, solder balls may be applied to the bottom contact pads 388 as illustrated for example in 4A-B, which show a solder ball 400 on each pad 388 in order to facilitate electrical connection. The dimensions of solder balls 400 may vary from product to product and the present technology is not limited to any particular dimensions. The present drawings are for illustration and various elements may differ from those illustrated. For example, while pads 388 are shown as having a square shape, pads may have other shapes (e.g., round) and while solder balls 400 are shown as having a spherical or ball shape, melting and/or other factors may cause solder balls to have other shapes (e.g., a “steamed bun” shape). The present technology is not limited to the examples illustrated in the drawings.

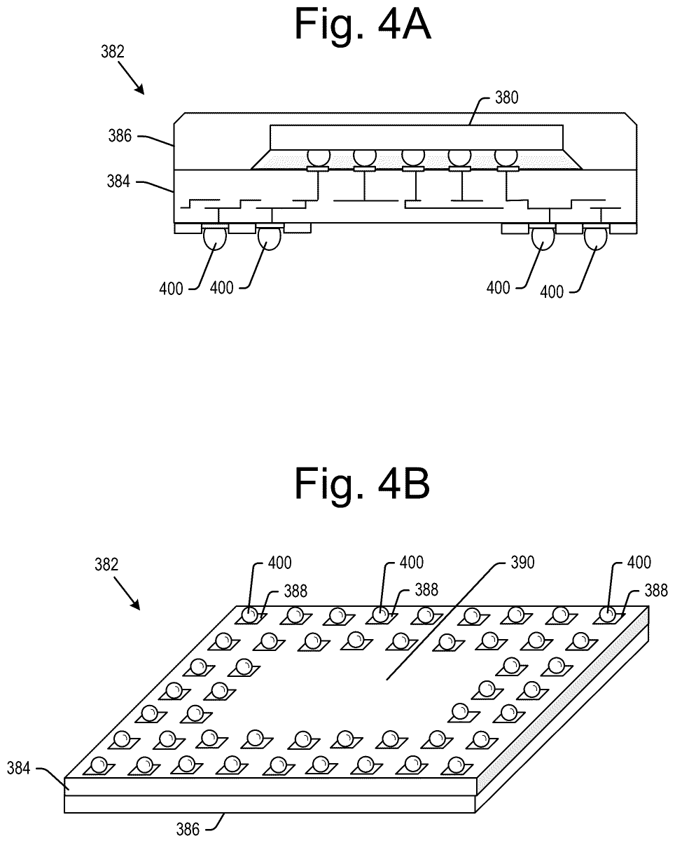

While FIGS. 3A-4B show an individual package 382, assembly, encapsulation and addition of solder balls may be performed on a panel that has multiple packages (e.g., substrate 384 may extend beyond what is shown in FIGS. 3A-4B to accommodate multiple packages, which may subsequently be singulated or separated from each other to form individual finished package 382. Package 382 may be singulated by any of a combination of cutting methods including sawing, water jet cutting, laser cutting, water guided laser cutting, dry media cutting, and diamond coating wire cutting.

In some examples, packages such as package 382 may be coated with an Electromagnetic Interference (EMI) protection layer (e.g., after singulation). When solder balls are present (as illustrated with respect to package 382 in FIGS. 4A-B), applying an EMI protection layer may be challenging. For example, an EMI protection layer may be formed of an electrically conductive material, which may tend to cause short circuits between solder balls if solder balls are not adequately protected. Also, a coating process may generate significant heat, which may affect solder balls if not adequately managed.

Aspects of the present technology are directed to protecting solder balls on a surface of a package (e.g., a package that includes one or more dies) in a manner that avoids deposition of EMI protection layer material on or near the solder balls and that efficiently manages heat.

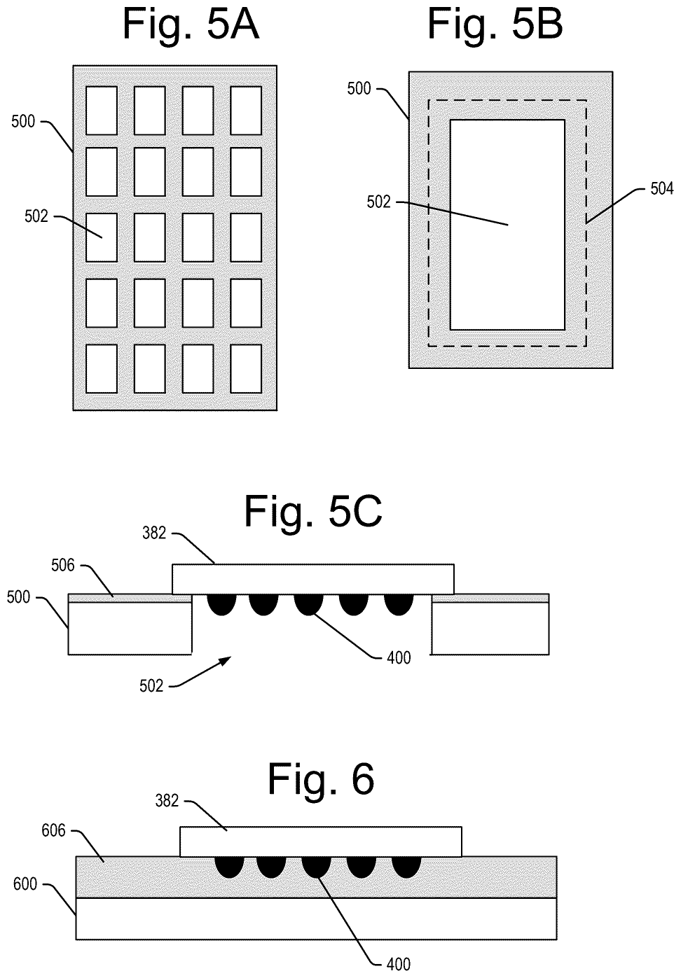

FIGS. 5A-C show an example of a window tape 500 that may be used to protect solder balls on a surface of a package such as package 382. FIG. 5A shows window tape 500, which includes windows or openings (e.g., opening 502) that extend through window tape 500. Openings are arranged in a grid pattern.

FIG. 5B illustrates opening 502 in window tape 500 with an outline 504 (dotted line) indicating the location of a package (e.g., package 382) to be attached to window tape 500. The dimensions of opening 502 are somewhat smaller than the dimensions of outline 504 and the location of outline 504 indicates how a package may be aligned to ensure some overlap between a package and window tape 500 all around opening 502.

FIG. 5C illustrates an example of package 382 after alignment and attachment to window tape 500. It can be seen that solder balls (e.g., solder ball 400) extend into opening 502. An adhesion layer 506 on the upper surface of window tape 500 is used to adhere package 382 to window tape 500. However, window tape with openings that extend through a tape may be relatively fragile and easily deformed, which may lead to some deposition in openings 502, which may cause electrical short circuits, damage to solder balls and/or other unwanted effects. Heat that may be generated by deposition of a conductive layer may not be effectively dissipated from package 382 in this arrangement because the bottom of package 382 is over opening 502.

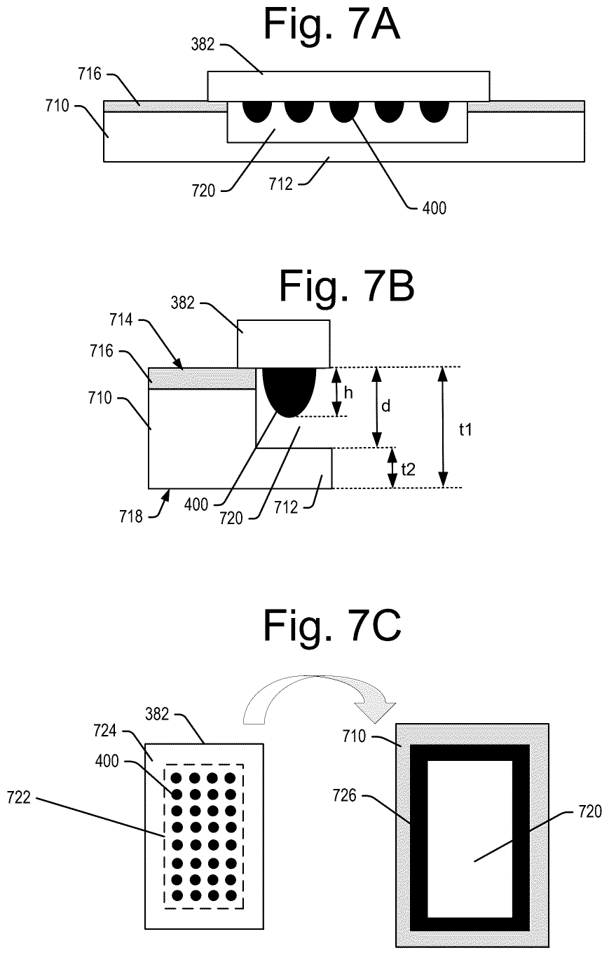

FIG. 6 shows an alternative approach that uses a solder embedded tape to protect solder balls. In this example, a tape 600 is provided with an adhesion layer 606 that is sufficiently thick to accommodate the solder balls (e.g., solder ball 400). For example, the thickness of adhesion layer 606 may be greater than the height of the solder balls so that solder balls become embedded in adhesion layer 606. In some cases, residue from adhesion layer 606 may remain on solder balls and/or the surface of package 382. Such residue may cause problems in subsequent process steps and/or may require additional cleaning steps for removal. And a thick adhesion layer used for embedded tape may be expensive and may cause various problems (e.g., over-coating, mis-coating and/or metal burr) because of difficulties of controlling solder conditions.

Aspects of the present technology provide solutions to technical problems associated with protecting solder balls of a workpiece (e.g., package such as package 382) during subsequent process steps (e.g., during deposition of an EMI protection layer), for example, reducing or eliminating unwanted deposition on solder balls and/or surface of a workpiece and adequately dissipating heat from a workpiece during subsequent steps.

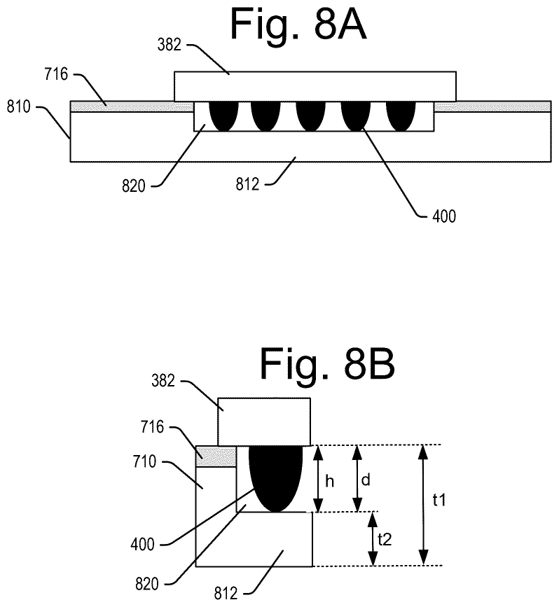

FIG. 7A shows a first example of a package (package 382) attached to a cavity tape 710 in cross section. Cavity tape 710 includes cavity 720, which accommodates solder balls (e.g., solder ball 400) and provides a space that may provide some clearance between solder balls and cavity tape 710. Unlike openings 502, cavity 720 does not extend through cavity tape 710 so that a portion 712 (base portion) of cavity tape 710 remains under cavity 720. This may make cavity tape 710 stronger and less prone to distortion than window tape and may provide additional protection from unwanted deposition (e.g., ensuring a good seal around edges of package 382). Cavity tape 710 includes an adhesion layer 716 that extends along the upper surface 714 of cavity tape 710. The edges of package 382 overlap adhesion layer 716 (e.g., cavity 720 has dimensions along upper surface 714 that are less than dimensions of corresponding package 382). Where package 382 overlaps adhesion layer 716 around cavity 720, adhesion occurs between package 382 and cavity tape 710 which may hold package 382 in place and seal cavity 720 (e.g., to protect solder balls 400 and the lower surface of package 382 during subsequent steps).

FIG. 7B shows some of the dimensions of features shown in FIG. 7A, including the thickness of cavity tape 710, t1, (from upper (first) surface 714 to lower (second) surface 718) and the depth of cavity 720, d (from first surface 714 to the bottom of cavity 720). The thickness of base portion 712, t2, is also shown and is equal to the tape thickness minus cavity depth, d (e.g., t2=t1−d). FIG. 7B also shows the height, h, of solder balls 400 (e.g., the distance solder balls extend from the surface of package 382). In this example, cavity 720 is configured to have a depth, d, that is greater than solder ball height (e.g., d>h). This results in a gap between solder ball 400 and base portion 712 that is equal to the difference between cavity depth and solder ball height (e.g., gap=d−h).

FIG. 7C shows how package 382 may be aligned with and attached to cavity tape 710. Package 382 is shown from below, with solder balls 400 located in a central area 722 (shown by dashed line) of the bottom surface of package 382. Peripheral area 724 extends around central area 722. Package 382 may be aligned with cavity 720 such that central area 722 of package 382 is disposed over cavity 720 and the solder balls 400 extend into cavity 720 with base portion 712 of the cavity tape 710 underlying cavity 720. Aligning package 382 with cavity 720 may be followed by adhering peripheral area 724 to cavity tape 710 with adhesion layer 716 in area 726 that extends between cavities of cavity tape 710 (around cavity 720) to seal cavity 720.

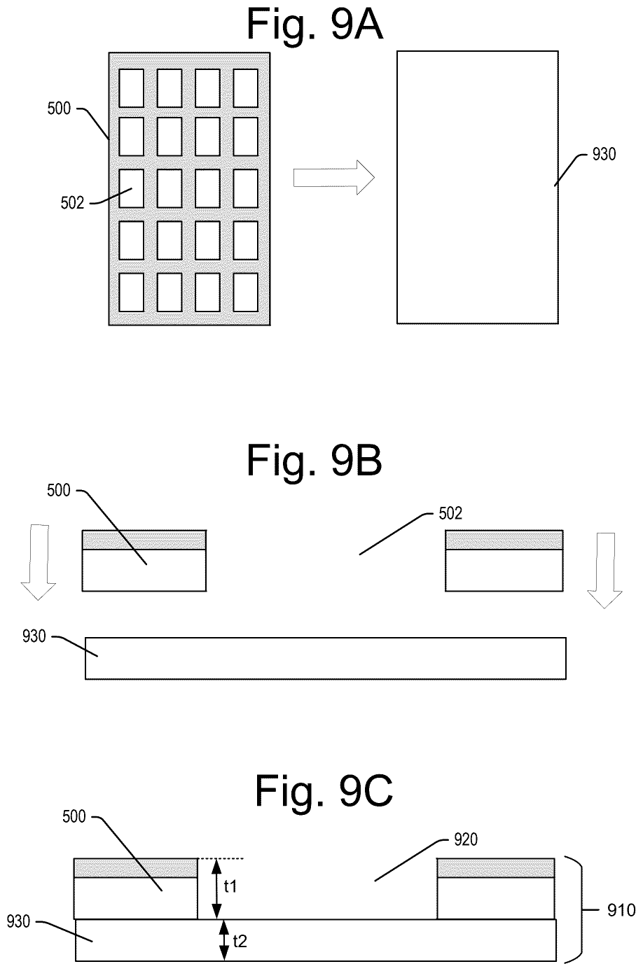

FIGS. 8A-B show another example of cavity tape 810, which has a cavity 820 with depth, d, equal or substantially equal to solder ball height, h. For example, cavity tape 810 may be formed of a relatively soft material that may deform when it contacts solder balls 400 so as not to cause damage. Such contact may provide a pathway for heat transfer during subsequent processing without leaving residue on solder balls 400. Cavity tape may be configured to ensure contact between solder balls and cavity tape (e.g., by configuring depth d to be equal, or somewhat less than solder ball height h, d≤h).

FIG. 8B illustrates that solder ball height, h, is equal to cavity depth, d, in this example. In other examples, cavity depth may be less than solder ball height by a relatively small amount such as less than 10% (e.g., d=h, d≈h, or 0.9*h<d<h) to ensure contact between solder balls and base portion 812 (e.g., base portion may deform to accommodate solder balls 400).

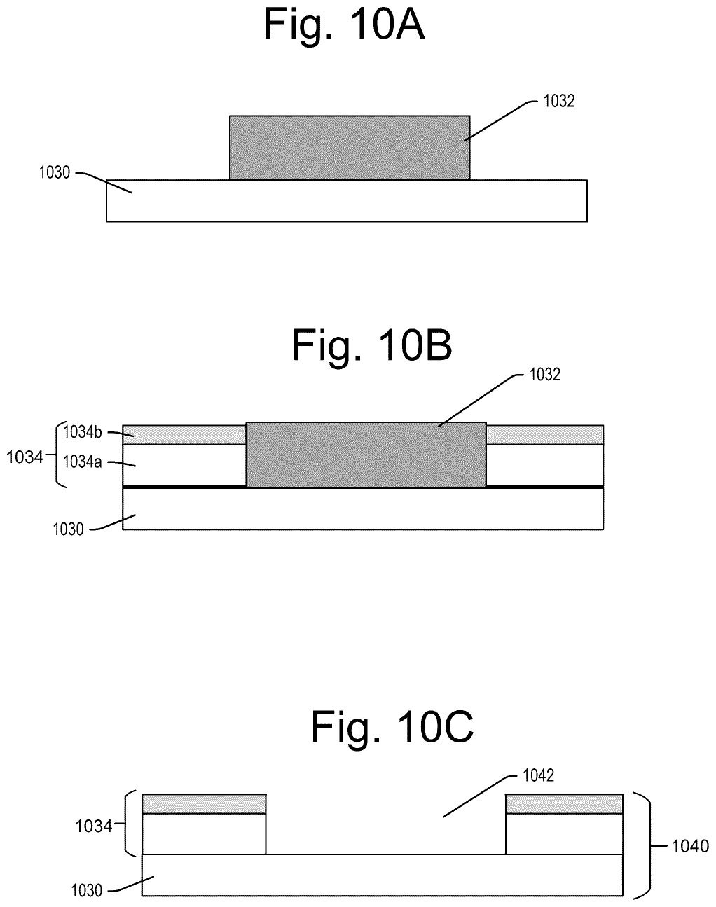

A cavity tape such as cavity tapes 710 and 810 may be made in any suitable manner from any suitable material (e.g., a heat-resistant polymer such as polyimide). FIGS. 9A-C show an example of making a cavity tape 910 from a window tape 500 (e.g., as previously described) and a base tape 930. Base tape 930 may be formed as a continuous sheet (e.g., without openings) of substantially uniform thickness (e.g., without cavities).

FIG. 9B shows window tape 500 in cross section being combined with base tape 930 by placing window tape 500 over base tape 930 and bonding or adhering to form a single structure with two layers, a window layer formed by window tape 500 and a base layer formed by base tape 930.

FIG. 9C shows cavity tape 910 that results from combining window tape 500 and base tape 930. A cavity 920 is formed by opening 502 when it is closed below by base tape 930. Such a structure may be stronger and less subject to deformation than window tape alone. It can be seen that the depth of cavity 920 is equal to the thickness of window tape 500 so that cavity depth is easy to control (e.g., window tape 500 has openings that extend through the window tape and has a first thickness, t1, that is equal to depth of the plurality of cavities, the base tape 930 having a second thickness, t2, that is equal to thickness of the base portion underlying cavity).

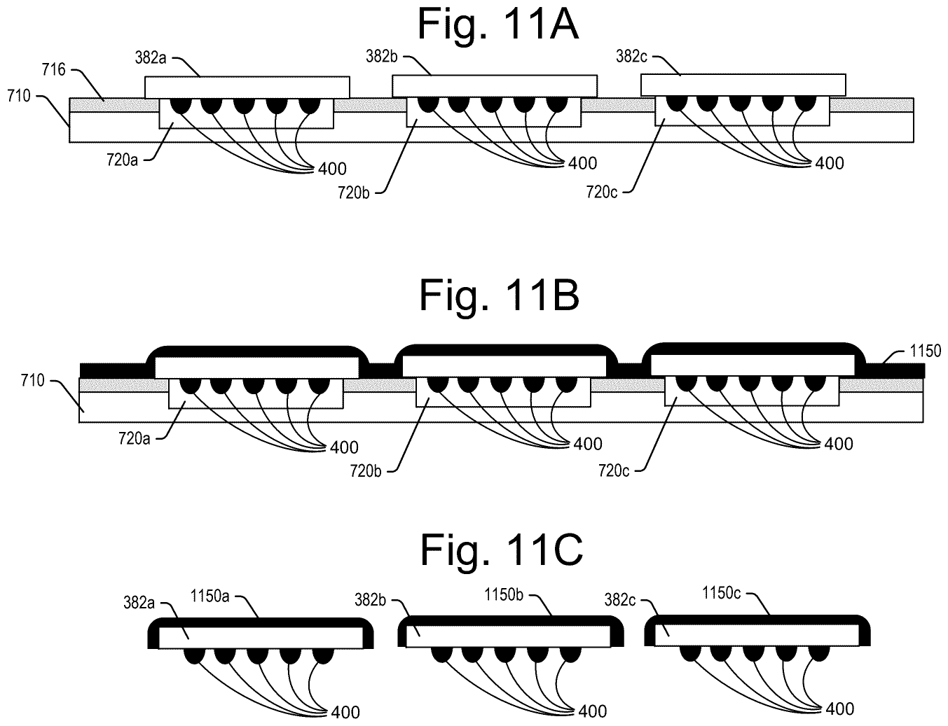

FIGS. 10A-C illustrate an example of making a cavity tape by patterning and adding material to build walls between cavities. FIG. 10A shows a base tape 1030 that has a portion of masking material 1032 on its upper surface. For example, a layer of masking material may be put on base tape 1030 and then patterned (e.g., by photolithography or otherwise) to leave portions of masking material in a desired pattern (e.g., covering locations corresponding to cavities). Subsequently, with portions of masking material 1032 in place, tape material and adhesive may be added on base tape 1030 to form walls between masking portions 1032 (e.g., wall 1034, which is formed of tape material 1034a and adhesive 1034b).

FIG. 10C shows cavity tape 1040 that is formed by removing masking portion 1032 to leave cavity 1042. Cavity tape 1040 may include an array of cavities 1042 separated by walls 1034 over base tape 1030.

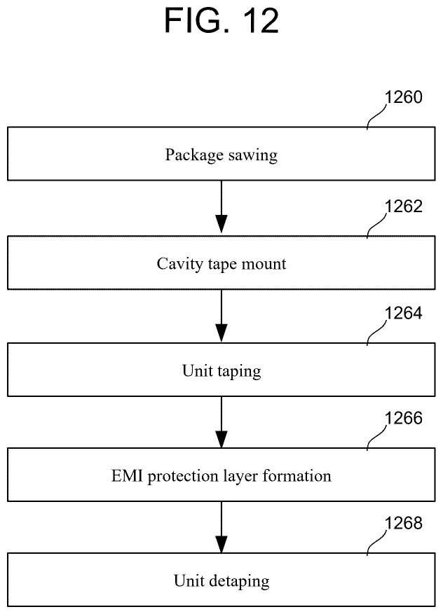

FIGS. 11A-C illustrate an example of using cavity tape 710. FIG. 11A shows cavity tape 710 in cross section with packages 382a-c in place. Solder balls 400 of packages 382a-c extend into corresponding cavities 720a-c (in other examples solder balls 400 may contact cavity tape 710 as show in FIGS. 8A-B). Adhesive layer 716 may hold packages 382a-c in place and seal cavities 720a-c.

FIG. 11B shows cavity tape 710 and packages 382a-c after deposition of an electrically conductive layer 1150 over packages 382a-c and exposed portions of cavity tape 710 between packages 782a-c. Electrically conductive layer 1150 may be formed of a conductive material or combination of materials. For example, one or more metals may be deposited by sputtering or otherwise. Examples of suitable metals may include copper, aluminum, tungsten and/or some combination of metals including metal alloys. Because solder balls 400 are sealed within cavities 720a-c during formation of electrically conductive layer 1150, they are protected from electrically conductive material that might otherwise cause short circuits or other problems.

FIG. 11C shows packages 382a-c after they are separated from cavity tape 710 (after “detaping” step). Each package 382a-c has a corresponding conductive layer portion 1150a-c extending over its upper surface and along its sides in the view of FIG. 11C while solder balls 400 remain clean of conductive material. Thus, packages 382a-c are provided with EMI protection without damaging solder balls 400.

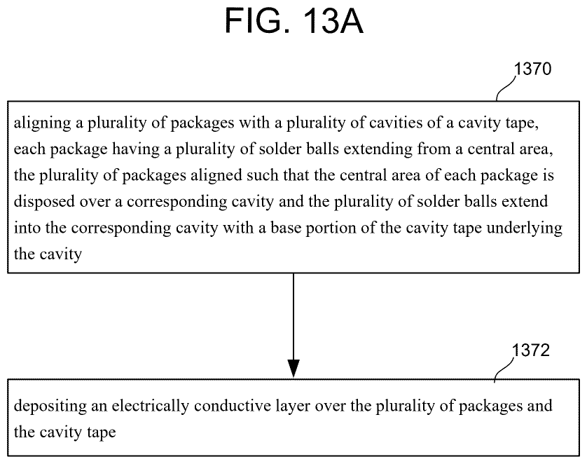

FIG. 12 illustrates steps according to a method that protects packages (e.g., solder balls on a surface of a package) during deposition of an electrically conductive layer that may be provided for EMI protection. The method includes package sawing 1260 in which individual packages (e.g., packages such as package 382) are separated (singulated) from a collection of physically-connected packages (e.g., a panel of packages) and cavity tape mount 1262 in which a cavity tape (e.g., cavity tape 710 or 810) is prepared for attachment of packages. This is followed by unit taping 1264, which includes attaching units (e.g., packages or workpieces) to a cavity tape (e.g., as shown in FIG. 11A) and EMI protection layer formation 1266 (e.g., deposition of an electrically conductive layer such as layer 1150). Subsequently, unit detaping 1268 includes separating units from the cavity tape (e.g., as shown in FIG. 11C).

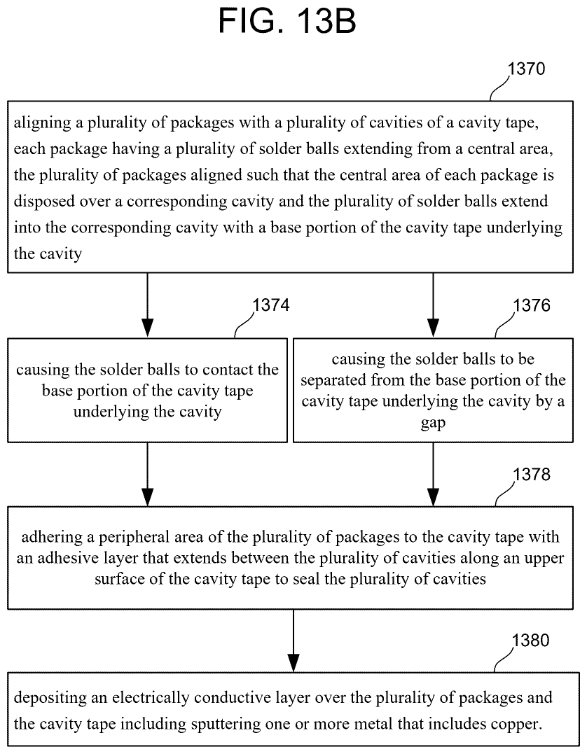

FIG. 13A shows an example of a method that includes aligning a plurality of packages with a plurality of cavities of a cavity tape, each package having a plurality of solder balls extending from a central area, the plurality of packages aligned such that the central area of each package is disposed over a corresponding cavity (e.g., as shown in FIG. 7C) and the plurality of solder balls extend into the corresponding cavity (e.g., as shown in FIGS. 7A-B and 8A-B) with a base portion of the cavity tape underlying the cavity 1370 and depositing an electrically conductive layer over the plurality of packages and the cavity tape 1372 (e.g., layer 1150).

FIG. 13B shows a more detailed example of a method that includes aligning a plurality of packages with a plurality of cavities of a cavity tape, each package having a plurality of solder balls extending from a central area, the plurality of packages aligned such that the central area of each package is disposed over a corresponding cavity (e.g., as shown in FIG. 7C) and the plurality of solder balls extend into the corresponding cavity (e.g., as shown in FIGS. 7A-B and 8A-B) with a base portion of the cavity tape underlying the cavity 1370 as previously discussed and either causing the solder balls to contact the base portion of the cavity tape underlying the cavity 1374 (e.g., as shown in FIGS. 8A-B) or causing the solder balls to be separated from the base portion of the cavity tape underlying the cavity 1376 (e.g., as shown in FIGS. 7A-B). The method further includes adhering a peripheral area of the plurality of packages to the cavity tape with an adhesion layer that extends between the plurality of cavities along an upper surface of the cavity tape to seal the plurality of cavities 1378 and depositing an electrically conductive layer over the plurality of packages and the cavity tape including sputtering one or more metal that includes copper 1380 (e.g., forming layer 1150 by sputtering a mix of metals that includes copper).

An example apparatus includes a tape having a tape thickness extending from a first surface to a second surface; and a plurality of cavities formed in the first surface. Each cavity has dimensions along the first surface that are less than dimensions of a corresponding package. Each cavity has a cavity depth that is less than the tape thickness such that base portion of the tape has a base thickness that is less than the tape thickness.

The cavity depth may be approximately equal to a height of solder balls located on a surface of the corresponding package. The cavity depth may be greater than the height of a plurality of solder balls located on a surface of the corresponding package. The tape may be formed of a high thermal stability material (e.g., stable above 200° C.), such as polyimide. The tape may further include an adhesion layer on the first surface of the tape. The tape may be formed of a base layer having the base thickness and a window layer overlying the base layer, the window layer attached to the base layer, each cavity extending through the window layer such that the cavity depth is equal to thickness of the window layer. The tape may be formed of a base layer having the base thickness and a plurality of walls extending up from the base layer and having a height equal to the cavity depth. The apparatus may further include a plurality of packages, each package including one or more encapsulated die, each package aligned with a corresponding cavity of the plurality of cavities and having solder balls that extend into the corresponding cavity. The apparatus may further include an electrically conductive layer extending over the plurality of packages and over exposed portions of the first surface between packages.

An example of a method includes aligning a plurality of packages with a plurality of cavities of a cavity tape, each package having a plurality of solder balls extending from a central area, the plurality of packages aligned such that the central area of each package is disposed over a corresponding cavity and the plurality of solder balls extend into the corresponding cavity with a base portion of the cavity tape underlying the cavity; and depositing an electrically conductive layer over the plurality of packages and the cavity tape.

The method may further include adhering a peripheral area of the plurality of packages to the cavity tape with an adhesion layer that extends between the plurality of cavities along an upper surface of the cavity tape to seal the plurality of cavities. The cavity tape may be formed by bonding a window tape with a base tape, the window tape having openings that extend through the window tape and having a first thickness that is equal to depth of the plurality of cavities, the base tape having a second thickness equal to thickness of the base portion underlying cavity. The cavity tape may be formed using a masking layer over a base tape and depositing tape material to form the plurality of cavities in a pattern established by the masking layer. The method may further include, prior to aligning the plurality of packages with the plurality of cavities: forming the plurality of packages by encapsulating a plurality of dies; forming the solder balls on the plurality of packages; and separating the plurality of packages. Depositing the electrically conductive layer may include sputtering one or more metal that includes copper. The method may further include causing the solder balls to contact the base portion of the cavity tape underlying the corresponding cavity. The method may further include causing the solder balls to be separated from the base portion of the cavity tape underlying the corresponding cavity by a gap.

An example apparatus includes a plurality of integrated circuit packages each having solder balls extending from a surface; and means for protecting the surfaces and solder balls of the plurality of integrated circuit packages during deposition of an Electromagnetic Interference (EMI) protection layer by enclosing the solder balls of each integrated circuit package in a corresponding cavity that extends from the surface to a base portion that underlies the corresponding cavity.

The apparatus may further include an adhesion layer formed on the means for protecting to adhere the plurality of integrated circuit packages to the means for protecting. Each of the integrated circuit packages may include at least one NAND flash memory die.

The foregoing detailed description has been presented for purposes of illustration and description. It is not intended to be exhaustive or to limit the invention to the precise form disclosed. Many modifications and variations are possible in light of the above teachings. The described embodiments were chosen in order to best explain the principles of the technology and its practical application, to thereby enable others skilled in the art to best utilize the technology in various embodiments and with various modifications as are suited to the particular use contemplated. It is intended that the scope of the technology be defined by the claims appended hereto.

What is claimed is:

1. An apparatus comprising:
a tape having a tape thickness extending from a first surface to a second surface; and
a plurality of cavities formed in the first surface, each cavity having dimensions along the first surface that are less than dimensions of a corresponding package, each cavity having a cavity depth that is less than the tape thickness such that base portion of the tape has a base thickness that is less than the tape thickness.

2. The apparatus of claim 1, wherein the cavity depth is approximately equal to a height of solder balls located on a surface of the corresponding package.

3. The apparatus of claim 1, wherein the cavity depth is greater than the height of a plurality of solder balls located on a surface of the corresponding package.

4. The apparatus of claim 1, wherein the tape is formed of polyimide.

5. The apparatus of claim 1, further comprising an adhesion layer on the first surface of the tape.

6. The apparatus of claim 1, wherein the tape is formed of a base layer having the base thickness and a window layer overlying the base layer, the window layer attached to the base layer, each cavity extending through the window layer such that the cavity depth is equal to thickness of the window layer.

7. The apparatus of claim 1, wherein the tape is formed of a base layer having the base thickness and a plurality of walls extending up from the base layer and having a height equal to the cavity depth.

8. The apparatus of claim 1, further comprising a plurality of packages, each package including one or more encapsulated die, each package aligned with a corresponding cavity of the plurality of cavities and having solder balls that extend into the corresponding cavity.

9. The apparatus of claim 8, further comprising an electrically conductive layer extending over the plurality of packages and over exposed portions of the first surface between packages.

10. A method comprising:
aligning a plurality of packages with a plurality of cavities of a cavity tape, each package having a plurality of solder balls extending from a central area, the plurality of packages aligned such that the central area of each package is disposed over a corresponding cavity and the plurality of solder balls extend into the corresponding cavity with a base portion of the cavity tape underlying the cavity; and
depositing an electrically conductive layer over the plurality of packages and the cavity tape.

11. The method of claim 10, further comprising adhering a peripheral area of the plurality of packages to the cavity tape with an adhesion layer that extends between the plurality of cavities along an upper surface of the cavity tape to seal the plurality of cavities.

12. The method of claim 10, wherein the cavity tape is formed by bonding a window tape with a base tape, the window tape having openings that extend through the window tape and having a first thickness that is equal to depth of the plurality of cavities, the base tape having a second thickness equal to thickness of the base portion underlying cavity.

13. The method of claim 10, wherein the cavity tape is formed using a masking layer over a base tape and depositing tape material to form the plurality of cavities in a pattern established by the masking layer.

14. The method of claim 10, further comprising, prior to aligning the plurality of packages with the plurality of cavities:
forming the plurality of packages by encapsulating a plurality of dies;
forming the solder balls on the plurality of packages; and
separating the plurality of packages.

15. The method of claim 10, wherein depositing the electrically conductive layer includes sputtering one or more metal that includes copper.

16. The method of claim 10, further comprising causing the solder balls to contact the base portion of the cavity tape underlying the corresponding cavity.

17. The method of claim 10, further comprising causing the solder balls to be separated from the base portion of the cavity tape underlying the corresponding cavity by a gap.

18. An apparatus comprising:
a plurality of integrated circuit packages each having solder balls extending from a surface; and
means for protecting the surfaces and solder balls of the plurality of integrated circuit packages during deposition of an Electromagnetic Interference (EMI) protection layer by enclosing the solder balls of each integrated circuit package in a corresponding cavity that extends from the surface to a base portion that underlies the corresponding cavity.

19. The apparatus of claim 18, further comprising an adhesion layer formed on the means for protecting to adhere the plurality of integrated circuit packages to the means for protecting.

20. The apparatus of claim 19, wherein each of the integrated circuit packages includes at least one NAND flash memory die.
